(19) United States
(12) Patent Application Publication
(10) Pub. No.: US 2003/0226090 A1
(43) Pub. Date: Dec. 4, 2003

(54) System and method for preventing memory access errors

(76) Inventor: Larry Jay Thayer, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/156,528

(22) Filed: May 28, 2002

(51) Int. Cl. G11C 29/00

(52) U.S. Cl. 714/763

(57) ABSTRACT

A system for preventing memory access errors utilizes a memory chip and logic. The memory chip has a plurality of memory locations. The logic is external to the memory chip and is configured to receive a signal indicative of whether a received memory address is associated with a detected parity error. The logic is further configured to enable the memory chip to access the memory locations based on the memory address if the signal indicates that the memory address is not associated with a detected parity error, and to disable the memory chip from accessing the memory locations based on the memory address if the signal indicates that the received address is associated with a detected parity error.

### BACKGROUND OF THE INVENTION

1. Field of the Invention

The present invention generally relates to memory systems and, in particular, to a system and method for preventing memory access errors.

2. Related Art

Parity checking is typically employed within computer systems for detecting transmission errors that occur when data is being communicated from one component of the computer system to another. For example, it is common for a processing element, such as a central processing unit (CPU), within a computer system to submit data access requests (i.e., read or write requests) across a system bus to a memory subsystem, which retrieves or stores data in various memory chips within the memory subsystem in response to the data access requests. Such a data access request normally includes a bus address that is utilized by the memory subsystem to service the data access request, and parity checking is sometimes employed in an attempt to ensure that the bus address received by the memory subsystem is the same bus address transmitted by the processing element.

U.S. Pat. No. 6,308,297 to Harris suggests the concept of employing parity checking techniques within a memory chip to prevent memory access errors. In this regard, Harris describes a memory subsystem that comprises a plurality of memory chips where data can be stored and retrieved. A memory controller within the memory subsystem is interfaced with the memory chips and generally controls the processes of storing and retrieving data to and from the memory chips. Address verification logic within each memory chip analyzes the memory addresses received from the memory controller and determines whether or not each of the memory addresses is associated with a parity error. If a received memory address is indeed associated with a parity error, the address verification logic prevents access to the memory within the memory chip, thereby preventing a potential memory access error.

However, in order to include address verification logic, many conventional memory chips may have to be redesigned, thereby potentially increasing the manufacturing cost of at least some types of memory chips. In this regard, memory chips are typically low-cost, high-volume products, and the costs of reconfiguring a manufacturing process for manufacturing memory chips capable of preventing memory access errors, as taught in Harris, can be significant.

### SUMMARY OF THE INVENTION

Generally, the present invention provides a system and method for preventing memory access errors.

A system in accordance with an exemplary embodiment of the present invention utilizes a memory chip and logic. The memory chip has a plurality of memory locations. The logic is external to the memory chip and is configured to receive a signal indicative of whether a received memory address is associated with a detected parity error. The logic is further configured to enable the memory chip to access the memory locations based on the memory address if the signal indicates that the memory address is not associated with a detected parity error, and to disable the memory chip from accessing the memory locations based on the memory address if the signal indicates that the received address is associated with a detected parity error.

The present invention can also be viewed as providing a method for preventing memory access errors. The method can be broadly conceptualized by communicating a memory address for identifying one of a plurality of memory locations within a memory chip, receiving, external to the memory chip, a signal indicative of whether the memory address is associated with a detected parity error, analyzing, external to the memory chip, the signal received in the receiving step, and disabling, based on the analyzing step, the memory chip from utilizing the memory address to access the memory locations

### BRIEF DESCRIPTION OF THE DRAWINGS

The invention can be better understood with reference to the following drawings. The elements of the drawings are not necessarily to scale relative to each other, emphasis instead being placed upon clearly illustrating the principles of the invention. Furthermore, like reference numerals designate corresponding parts throughout the several views.

FIG. 1 is a block diagram illustrating a computer system employing a memory subsystem in accordance with an exemplary embodiment of the present invention.

FIG. 2 is a block diagram illustrating a memory subsystem, such as is depicted in FIG. 1.

FIG. 3 is a block diagram illustrating a memory module, such as is depicted in FIG. 2.

FIG. 4 is a block diagram illustrating error detection logic, such as is depicted in FIG. 3.

FIG. 5 is a block diagram illustrating a chip select control unit, such as is depicted in FIG. 4.

FIG. 6 is a flow chart illustrating an exemplary embodiment of an architecture and functionality of error detection logic, such as is depicted in FIG. 3, according to the present invention.

FIG. 7 is a flow chart illustrating an exemplary embodiment of an architecture and functionality of retrieval and storage logic, such as is depicted in FIG. 3, according to the present invention.

### DETAILED DESCRIPTION

In general, the present invention pertains to memory access error prevention within a memory system or subsystem. In this regard, a memory system or subsystem in accordance with a preferred embodiment of the present invention comprises one or more memory chips having a plurality of memory locations where data can be stored and retrieved. Before a memory address is provided for the purpose of accessing a memory location within the memory chip, error detection logic preferably analyzes the address in an attempt to detect a transmission or parity error associated with the address. If the error detection logic detects such an error, the error detection logic prevents the chip's memory from being accessed based on the erroneous address.

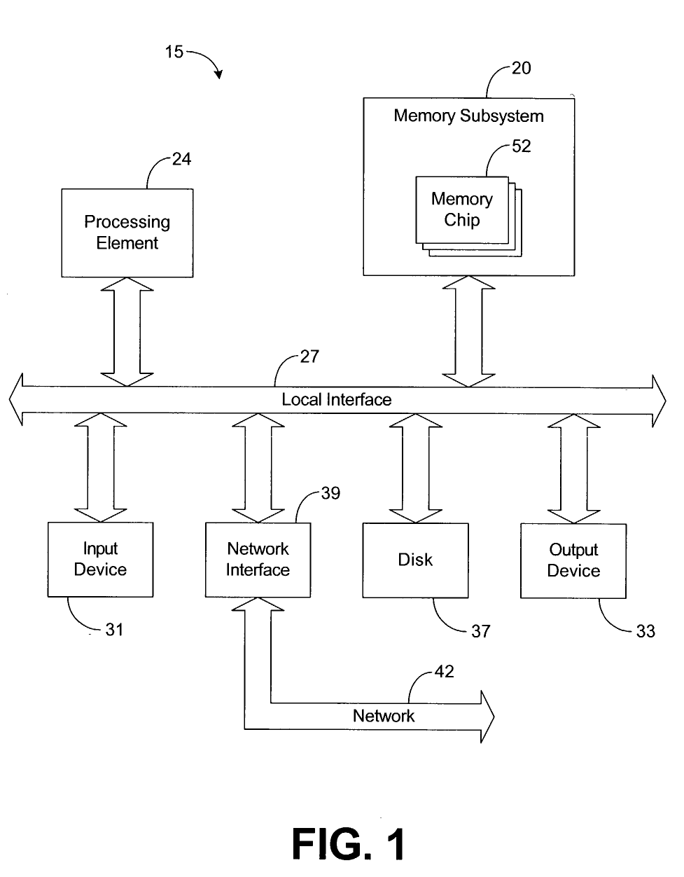

FIG. 1 depicts an exemplary computer system 15 employing a memory subsystem 20 in accordance with a preferred embodiment of the present invention. The computer system 15 depicted by FIG. 1 comprises one or more conventional processing elements 24, such as a digital signal processor (DSP) or a central processing unit (CPU), that communicate to and drive the other elements within the system 15 via a local interface 27, which can include one or more buses. Furthermore, an input device 31, for example, a keyboard or a mouse, can be used to input data from a user of the system 15, and an output device 33, for example, a screen display or a printer, can be used to output data to the user. A disk storage mechanism 37 can be connected to the local interface 27 to transfer data to and from a nonvolatile disk (e.g., magnetic, optical, etc.). The local interface 27 can also be connected to a network interface 39 that allows the system 15 to exchange data with a network 42.

The memory subsystem 20 of FIG. 1 comprises a plurality of memory chips 52. Each of the memory chips 52 is preferably an integrated circuit (IC) having a plurality of addressable memory locations where data can be stored and retrieved. In the preferred embodiment, each of the memory chips 52 comprises dynamic random access memory (DRAM). However, it should be emphasized that, in other embodiments, the memory chips 52 may implement other types of memory, such as, for example, static random access memory (SRAM) or other types of known or future-developed memory.

During operation, the processing element 24 may generate a data access request for storing data to or retrieving data from a memory location within one of the memory chips 52. This data access request is transmitted to the memory subsystem 20, which services the request. In this regard, if the data access request is for writing data, the data access request preferably includes a bus address and a data value, and the memory subsystem 20 stores the data in a memory location of one or more memory chips 52 based on the bus address. If the data access request is for reading data, the data access request preferably includes a bus address, and the memory subsystem 20 retrieves data from a memory location of one or more memory chips 52 based on the bus address. The memory subsystem 20 then transmits the retrieved data to a location (e.g., a register within the processing element 24) specified by the data access request.

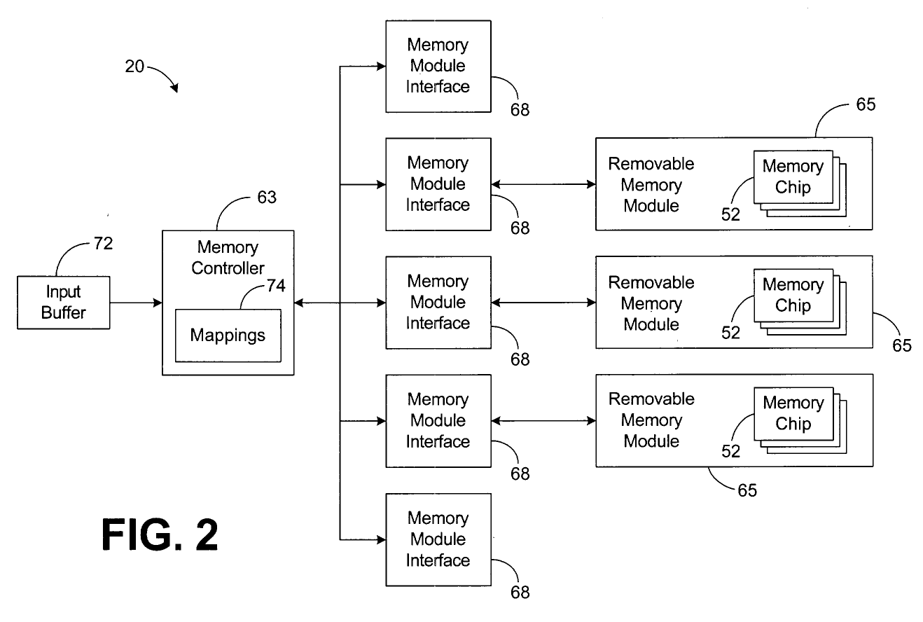

As shown by FIG. 2, the memory subsystem 20 preferably comprises a memory controller 63 and a plurality of removable memory modules 65 where the memory chips 52 reside. The memory controller 63 depicted by FIG. 2 is coupled to one or more memory module interfaces 68 that interface the memory modules 65 with the memory controller 63. In the preferred embodiment, each of the removable memory modules 65 is detachably coupled to one of the memory module interfaces 68, which provides a conductive connection between the memory module 65 and the memory controller 63.

Each of the memory module interfaces 68 may comprise various known or future-developed interface devices capable of providing a conductive connection between the memory controller 63 and a removable memory module 65. Such interface devices may comprise plug-in connectors to allow the removable memory module to be easily detached from the memory controller 63. As an example, the memory controller 63 and each of the removable memory modules 65 may be implemented on separate printed circuit boards, and each of the memory module interfaces 68 may comprise printed circuit board edge connectors (not specifically shown) that are interconnected for providing a conductive connection between a memory module 65 and the memory controller 63.

Utilization of interfaces 68 and memory modules 65 that are capable of being easily joined together and then separated helps in adapting the performance of the system 15 to the needs or desires of a user. For example, initially, a small number of memory modules 65 may adequately meet the memory requirements of the system 15. Thus, only a small number of memory modules 65 may initially be installed in the system 15. Later, if the user desires to increase the memory capacity of the system 15, the user may simply interface additional memory modules 65 with one of the memory module interfaces 68. Furthermore, if one of the memory modules 65 becomes defective, the user may replace the defective memory module 65 with a new memory module 65.

As previously described above, the memory subsystem 20 may receive, from the processing element 24 or other component of the system 15, a data access request for storing to or retrieving from one or more of the memory chips 52. This data access request preferably comprises a bus address and is buffered by an input buffer 72. As will be described in more detail below, each data access request buffered by the input buffer 72 is preferably serviced by the memory controller 63.

In this regard, the memory controller 63 preferably maintains a plurality of mappings 74 for mapping bus addresses to memory locations. When the memory controller 63 is servicing a data access request, the memory controller 63, based on the mappings 74, maps the bus address of the data access request to the memory locations that are to be accessed in response to the data access request. If the data access request is for writing data, the memory controller 63 stores data at the mapped memory locations. If the data access request is for reading data, the memory controller 63 retrieves data from the mapped memory locations.

When the memory controller 63 maps a bus address to a particular memory location of a particular memory chip 52, the memory controller 63 preferably transmits a memory address to the particular memory chip. This memory address preferably comprises a chip select portion, an offset portion, and a read/write indicator. The chip select portion indicates whether the memory chip 52 is to access a memory location in response to the memory address, and the offset portion identifies the particular memory location that is to be accessed in response to the memory address. Furthermore, the read/write indicator indicates whether the memory chip 52 is store or retrieve data in response to the memory address.

As an example, assume that the memory controller 63 receives, from the buffer 72, a data access request for writing a data value to a plurality of memory chips 52 within the memory subsystem 20. More specifically, each of the plurality of memory chips 52 is to write a portion of the data value in its memory. Each such chip 52 receives, from the memory controller 63, a memory address and the portion of the data value that is to be stored by the memory chip 52. The chip select of the received memory address indicates that the chip 52 is to respond to the memory address for accessing a location within the chip's memory. The read/write bit of the received memory address indicates that the memory chip 52 is to perform a write in response to the memory address, and the offset identifies the memory location where the received data value portion is to be written.

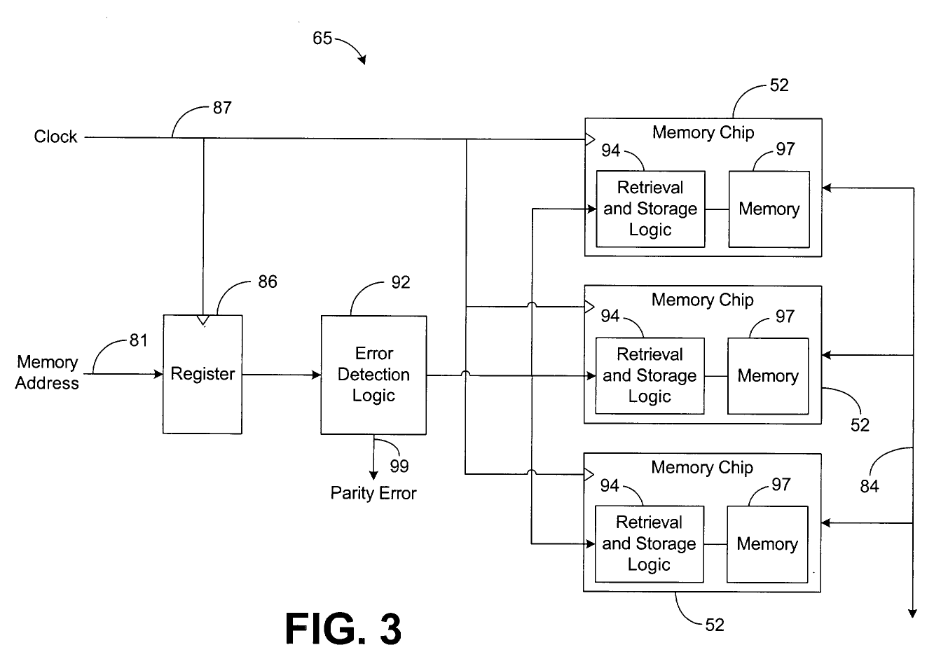

Note that the data defining the aforementioned memory address may be transmitted via an address bus 81 (FIG. 3) that extends from the memory controller 63 through a memory module interfaces 68 to the memory module 65 of the memory chip 52. Furthermore, the data defining the data value to be stored may be transmitted via a data bus 84 (FIG. 3) that also extends from the memory controller 63 through a memory module interface 68 to the memory module 65 of the,memory chip 52.

As shown by FIG. 3, for each of the modules 65, the memory address data received from the address bus 81 is input to a register 86. Based on a clock signal 87, the data is clocked out of the register 86 and is analyzed by error detection logic 92 before it is provided to each of the memory chips 52.

As will be described in more detail hereafter, the error detection logic 92 preferably tests the received memory address for transmission errors. If no transmission errors are detected by the error detection logic 92, then storage and retrieval logic 94 within each memory chip 52, in the present example, stores data from the data bus 84. More specifically, the storage and retrieval logic 94 of a particular chip 52 stores a data value received from the address bus 84 at the memory location identified by the offset of the memory address. Note that the storage and retrieval logic 94 is preferably implemented in hardware, although the logic 94 may be implemented in software or a combination of hardware and software in other embodiments.

Note that, in the embodiment depicted by FIG. 3, each of the memory chips 52 receives the same memory address such that, when any one of the chips 52 performs a data write or read, the other chips 52 similarly perform a data write or read. However, in other embodiments, it is possible for one or more of the memory chips 52 on the same memory module 65 to receive a different memory address and, therefore, access memory independent of the other memory chips 52.

In another example, assume that the memory controller 63 receives, from the buffer 72, a data access request for reading a data value from a plurality of memory chips 52 within the memory subsystem 20. More specifically, each of the plurality of memory chips 52 is to retrieve a portion of the data value that is stored in its memory 97 and to transmit the retrieved portion to the memory controller 63, which coalesces the retrieved portions into the requested data value. In this regard, each such chip 52 receives, from the memory controller 63, a memory address. The chip select of the received memory address indicates that the chip 52 is to respond to the memory address for accessing a location within the chip's memory 97. The read/write bit of the received memory address indicates that the memory chip 52 is to perform a read in response to the memory address, and the offset identifies the memory location that is to be read in response to the memory address.

Note that, as described above in the previous example, the foregoing memory address may be transmitted via the address bus 81 (FIG. 3). For each of the modules 65, the memory address on the address bus 81 is input to a register 86 and is provided to each of the memory chips 52 after passing through the error detection logic 92. If no transmission errors are detected by the error detection logic 92, then the storage and retrieval logic 94 of each memory chip 52 retrieves a data value from the chip's memory 97. More specifically, the logic 94 retrieves the data value stored at the memory location identified by the offset of the memory address. The storage and retrieval logic 94 of the identified memory chip 52 then outputs this data value across the data bus 84. The memory controller 63 receives each of the retrieved data values and, after coalescing the retrieved data values into a larger data value, transmits this larger data value to the location specified by the data access request.

In some instances, errors in the transmissions of the bus addresses and/or the memory addresses may occur such that the memory address actually received by a memory module 65 is incorrect. Such transmission errors may cause data to be written into wrong memory locations and/or may cause data to be retrieved from wrong memory locations resulting in a memory access error. As used herein, a “memory access error” occurs when an error in transmitting a memory address from one location to another causes a wrong memory location (i.e., a location not identified by the originally transmitted memory address) to be accessed.

In an effort to prevent memory access errors, the error detection logic 92 preferably analyzes the memory address received from the address bus 81 and performs parity error checking on this memory address. As used herein, the term “parity error checking” refers to any technique for analyzing data for the purpose of identifying errors that may occur when the data is being transmitted from one location to another, and “parity information” refers to any information that may be utilized to perform parity error checking.

Various parity error checking techniques are known in the art for verifying the accuracy of data transmitted from one location to another. Normally, parity error checking techniques involve appending a parity bit to a set of data that is to be communicated to another location. The parity bit may always be set to a particular value (e.g., a “1” or “0”) before transmission, or the parity bit may be set based on the data set being transmitted. For example, the parity bit may be set such that the number of ones in the data set, including the parity bit, is always odd, or the parity bit may be set such that the number of ones in the data set, including the parity bit, is always even.

Once the data set is received, the parity bit can be analyzed to determine whether a transmission error occurred during the transmission. For example, if the parity bit is always set to a particular value (e.g., a “1” or “0”), the parity bit may be analyzed to verify that the parity bit of the received data set is indeed set to the particular value. Alternatively, if the parity bit is set such that the number of ones is always either even or odd, then the number of ones in the received data set, including the parity bit, can be analyzed to verify that this number is indeed even or odd, as appropriate. Note that any known or future-developed techniques for parity checking may be employed by the error detection logic 92 in order for the logic 92 to verify that the memory address received from the address bus 81 is accurate or, in other words, that no errors occurred in the transmission of the received address.

In the preferred embodiment, the parity information in the memory address received by the memory module 65 is generated or otherwise provided by the memory controller 63, although other components of the system 15 may generate or provide the parity information in other embodiments. Moreover, before transmitting a memory address to a memory module 65, the memory controller 63 preferably includes parity information in the memory address such that the error detection logic 92 can determine, based on the parity information, whether any transmission errors occurred between the memory controller 63 and the error detection logic 92. Note that transmission of a memory address through a memory module interface 68 may be a likely source of error, depending on the types of devices utilized to implement the interface 68.

When the error detection logic 92 detects a parity error associated with the received memory address, the error detection logic 92 preferably asserts a parity error signal 99 (FIG. 3). This parity error signal 99 may be transmitted to the memory controller 63, which may be responsive to the parity error signal for performing various functionality.

For example, if the logic 92 asserts the signal 99, the memory controller 63 may be configured to record the error and thereby keep track of all the parity errors detected by the logic 92. A user may then retrieve this information from the memory controller 63 to evaluate the performance of the memory subsystem 20. In addition, the memory controller 63, in response to a parity error detection for a particular memory address, may reattempt transmission of the address to the memory modules 65 in an effort to successfully complete the data access request associated with the memory address. In addition, the memory controller 63 may transmit a notification message to another component of the system 15 in response to an asserted parity error signal 99. For example, the memory controller 63 may transmit the message to the output device 33, which displays the message to notify a user of the system 15 about the parity error detection. Various other steps may be performed by the memory controller 63 and/or other components of the system 15 in response to a parity error detection by the error detection logic 92.

In addition, the logic 92 is preferably configured to prevent memory access errors by preventing the memory chips 52 from responding to memory addresses that include parity errors. In this regard, when the error detection logic 92 detects a parity error based on the parity information included in a received memory address, the logic 92 may be configured to prevent or, in other words, disable the memory chips 52 from accessing the chips' memory 97 based on this memory address, thereby preventing an erroneous data store or an erroneous data retrieval based on the foregoing memory address.

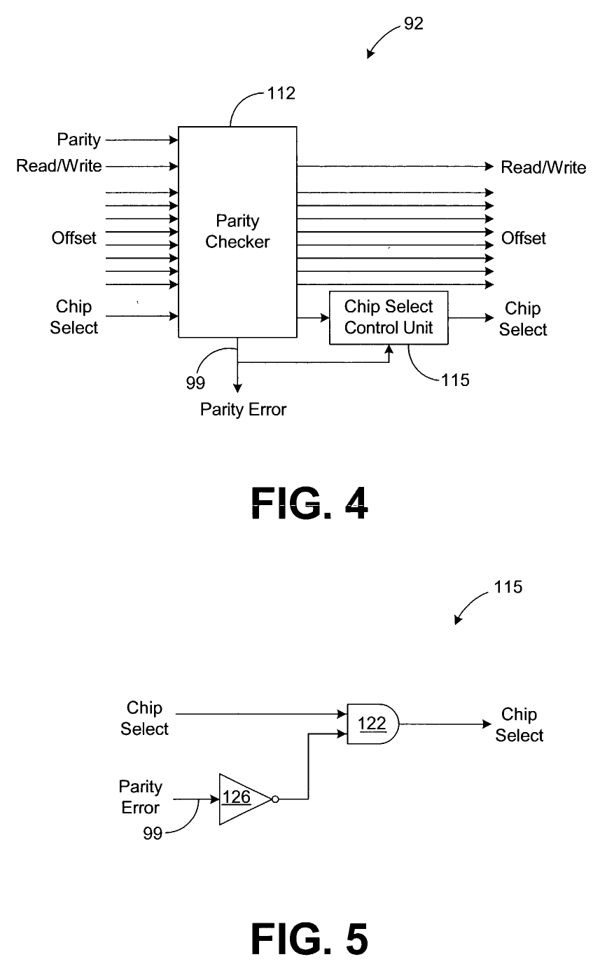

Note that there are a variety of methodologies that may be employed by the error detection logic 92 to prevent the memory chips 52 from responding to a memory address associated with a parity error. A suitable methodology for the preferred embodiment will now be described in more detail with reference to FIG. 4, in particular.

As shown by FIG. 4, the error detection logic 92 preferably comprises a parity checker 112 and a chip select control unit 115. The parity checker 112 and the chip select control unit 115 are preferably implemented in hardware, although these components may be implemented in software or a combination of hardware and software in other embodiments. As will be described in more detail hereafter, the parity checker 112 detects whether a received memory address has a detectable parity error, and based on information from the parity checker 112, the chip select control unit 115 prevents the memory chips 52 from responding to memory addresses associated with detectable parity errors.

As previously set forth above, the memory address received from the address bus 81 preferably comprises a chip select portion, an offset portion, a parity bit, and a read/write bit, although the memory address may comprise additional information or other combinations of information in other embodiments. The chip select portion indicates whether the memory chip 52 that receives the address is to respond to the memory address, and the offset portion identifies the memory location where data is to be read or written in response to the memory address. Further, the parity bit comprises parity information transmitted by the memory controller 63 for enabling the error detection logic 92 to verify the accuracy of the memory address, and the read/write bit indicates whether data should be read from the identified memory location or written to the identified memory location in response to the memory address. If desired, the parity information may be defined by more than a single bit.

In the embodiment depicted by FIG. 4, the parity checker 112 receives, as an input, a memory address transmitted across the address bus 81 by the memory controller 63. This memory address is preferably clocked out of the register 86 based on the clock signal 87. The parity checker 112 is configured to analyze the parity bit and, if necessary for verification of the memory address, the other portions of the memory address. Based on this analysis, the parity checker 112 determines whether a parity error is present in the memory address. If the parity checker 112 detects a parity error, the parity checker 112 asserts the parity error signal 99. Otherwise, the parity checker 112 deasserts the signal 99.

After the parity check is performed by the parity checker 112, the parity checker 112 outputs the memory address to one or more memory chips 52 preferably residing on the same memory module 65. However, the chip select portion of the memory address is preferably passed through the chip select control unit 115 before being received by the memory chips 52. If the parity error signal 99 is deasserted, then the parity checker 112 has failed to detect a parity error. In such a case, the chip select control unit 115 allows the chip select portion to pass without adjusting or modifying the chip select portion, thereby enabling a memory chip 52 to access its memory 97 based on the foregoing memory address.

However, if the parity error signal 99 is asserted, then the parity checker 112 has detected a parity error. In such a case, the chip select control unit 115 preferably suppresses the chip select portion of the memory address. In this regard, the chip select control unit 115 adjusts the chip select portion such that the chip select portion indicates that the receiving chip 52 is not to respond to the memory address. As a result, none of the memory chips 52 receiving the memory address responds to the memory address, thereby preventing a potential memory access error.

Note that there are a variety of methodologies that may be employed to suppress the chip select portion when a parity error is detected by the parity checker 112. As an example, assume that the chip select portion of a received memory address comprises a single bit of information. Further assume that, when asserted (e.g., a logical high), the chip select portion indicates that the receiving chip 52 is to respond to the memory address, and assume that, when deasserted (e.g., a logical low), the chip select portion indicates that the receiving chip 52 is not to respond to the memory address. Note that, in other embodiments, the chip select portion may be comprised of a plurality of bits. Circuitry suitable for implementing the chip select control unit 115, in this example, is depicted in FIG. 5.

In this regard, the circuitry depicted by FIG. 5 comprises an AND gate 122 and an inverter 126. As shown by FIG. 5, the parity error signal 99 transmitted from the parity checker 112 is preferably input to the AND gate 122 through an inverter 126, and the chip select bit is preferably input to the same AND gate 122. Moreover, if the parity error signal 99 is deasserted (e.g., a logical “low”) indicating no parity error detection, the output of the AND gate 122 preferably matches the value of the chip select bit. Therefore, the chip select control unit 115 does not adjust the value of the chip select portion. However, if the parity error signal 99 is asserted (e.g., a logical “high”) indicating a parity error detection, the output of the AND gate 122 goes to a logical low regardless of the value of the chip select bit. As a result, the chip select bit, after passing through the AND gate 122, indicates that a receiving memory chip 52 is not to respond to the memory address.

Utilization of a chip select control unit 115 to suppress the chip select portion of an erroneous memory address (i.e., an address associated with a parity error) provides a convenient and reliable manner in which to prevent a memory access error induced by the erroneous memory address. However, it should be emphasized that other techniques for preventing the memory chips 52 from responding to erroneous memory addresses are possible in other embodiments.

It should also be noted that, although it is possible to position the error detection logic 92 at different locations, positioning the logic 92 on the memory module 65 as shown by FIG. 3 has various advantageous. In this regard, placing the error detection logic 92 on the memory module 65 allows the logic 92 to check for errors that occur to a memory address after transmission of the memory address by the memory controller 63. This can be a particularly important feature for removable memory modules 65 that are detachably coupled to the memory controller 63 via memory module interfaces 68, as is described above for the modules 65. In this regard, misalignments and other problems associated with a memory module interface 68 may cause various transmission errors that are detectable by a parity checker 112 residing on the memory module 65, as shown by FIG. 3.

In addition, having the error detection logic 92 located external to the memory chips 52 can facilitate the implementation of the logic 92 within the memory subsystem 20. In this regard, by positioning the error detection logic 92 external to the memory chips 52, conventional memory chips may be employed to implement the chips 52 of the memory module 65 depicted in FIG. 3. Therefore, it is not necessary for memory chip manufacturers to change their current designs in order for memory address errors to be prevented according to the techniques described herein. Furthermore, each memory module 65 can be integrated via a printed circuit board, and an existing printed circuit board design can be easily modified to include the error detection logic 92. Moreover, the additional design and manufacturing costs associated with adding error detection logic 92 to a memory module 65 can be less significant relative to the overall costs of the memory module as compared to the additional design and manufacturing costs (relative to the overall cost of the memory chips 52) associated with adding error detection logic 92 to the memory chips 52.

It should be further noted that the present invention has been described above in the context of accessing memory locations for performing data reads and data writes. However, there may be other reasons for accessing memory locations, such as for performing pre-charges or memory refreshes, for example. The techniques described above may be employed in such examples to verify the memory addresses received by the modules 65 and to prevent memory access errors.

Furthermore, it should also be noted that the parity error detection techniques described above may be utilized to verify an entire memory address or just a portion of the memory address. For example, in one embodiment, parity error detection techniques may be employed to verify just one portion (e.g., the offset portion or some other portion) of a received memory address. In such an embodiment, a parity error is detected by the error detection logic 92 only if a transmission error occurs in the one portion of the received memory address. In another embodiment, parity error detection techniques may be employed to verify multiple potions of a received memory address. For example, parity error techniques may be employed to detect any transmission error occurring in either the offset portion or some other portion (e.g., the read/write bit) of a received memory address. In such an embodiment, a parity error is detected by the error detection logic 92 if a transmission error occurs in any of the portions verified by the logic 92. Note that the received memory address may comprise other portions not specifically discussed herein.

The preferred use and operation of the error detection logic 92 and associated methodology are described hereafter.

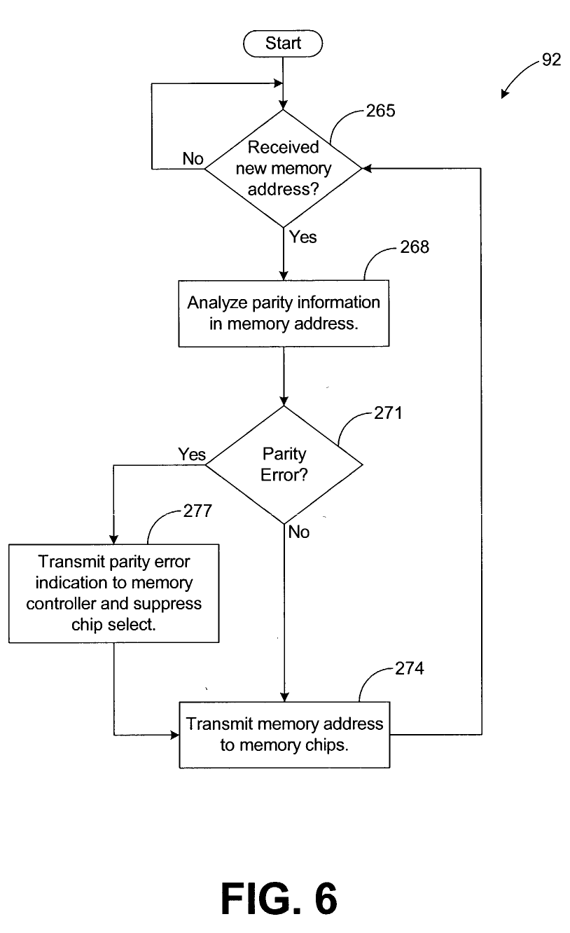

When a memory address is clocked out of the register 86 (FIG. 3) and received by the error detection logic 92, the error detection logic 92 analyzes the parity information of the memory address, as shown by blocks 265 and 268 of FIG. 6. If the error detection logic 92 fails to detect a parity error, then the logic 92 transmits the memory address to the module's memory chips 52 without adjusting the memory address, as depicted by blocks 271 and 274. However, if the error detection logic 92 detects a parity error, then the error detection logic 92 transmits a parity error indication via signal 99 and suppresses the chip select portion of the memory address, as depicted by blocks 271 and 277.

The suppression of the chip select portion in block 277 of FIG. 6 prevents any of the memory chips 52 on the memory module 65 from performing a data access based on the memory address. In this regard, as previously described above, the storage and retrieval logic 94 of each memory chip 52 is preferably designed to access, in response to a received memory address, the memory location identified by the memory address offset only if the chip select of the address is in an asserted state. Furthermore, when the error detection logic 92 suppresses the chip select, the logic 92 ensures that the chip select is forced to a deasserted state. Therefore, if the chip select portion is suppressed in block 277, each memory chip 52 refrains from accessing the identified memory location based on the received memory address.

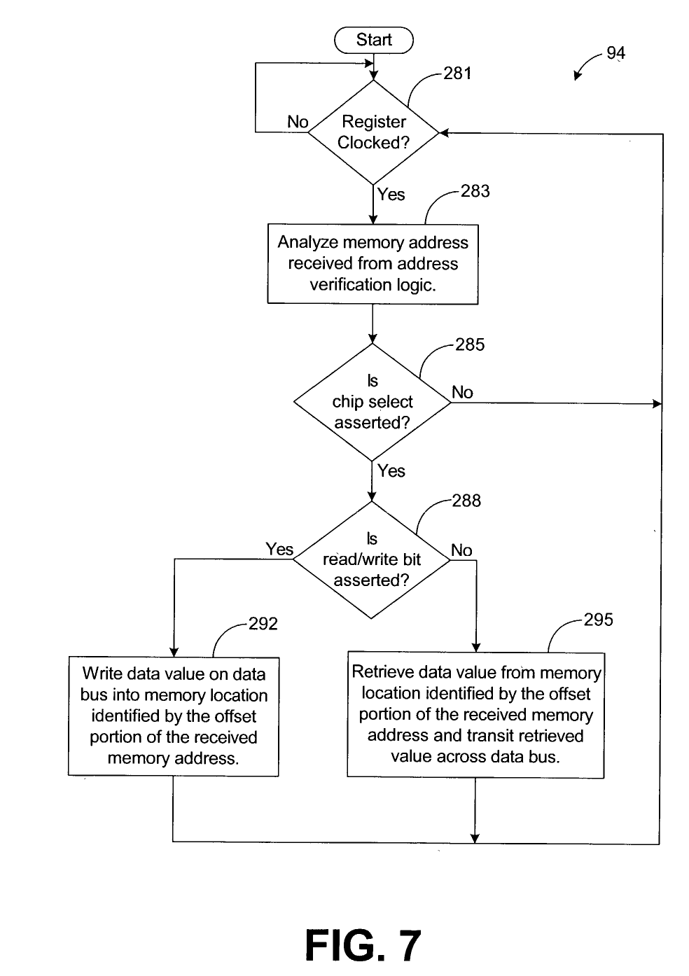

To better illustrate a preferred functionality of the storage and retrieval logic 94, refer to FIG. 7. As shown by blocks 281 and 283, the storage and retrieval logic 94 analyzes the memory address being received from the error detection logic 92 after the signal 87 (FIG. 3) clocks the register 86. As shown by block 285, if the chip select is deasserted, the logic 94 does not access the memory location identified by the received memory address and returns to block 281 to wait for the next memory address that will be transmitted upon the next clocking of the register 86. Note that the chip select may be deasserted due to implementation of block 277 in FIG. 6 when the error detection logic 92 detects a parity error associated with the received address, or the chip select may have been deasserted when the error detection logic 92 originally received the memory address.

If, on the other hand, the chip select of the received memory address is asserted, then the error detection logic 92 did not detect a parity error associated with the received address, and the storage and retrieval logic 94 responds to the memory address. In this regard, as shown by block 288, the logic 94 analyzes the read/write bit of the address to determine whether a data read or a data write is to be performed in response to the received memory address.

If the read/write bit is asserted, the received memory address is associated with a data write. Thus, the storage and retrieval logic 94 writes, into the memory location identified by the offset of the received memory address, the data value being received from the address bus 84, as shown by block 292. The logic 94 then returns to block 281 to wait for the next memory address that will be transmitted upon the next clocking of the register 86.

If the read/write bit is deasserted, then the memory address is associated with a data read. Thus, the logic 94 reads a data value from the memory location identified by the offset portion of the memory address. The memory chip 52 then transmits this retrieved data value across the data bus 84, as shown by block 295. The memory controller 63 receives this value and transmits this value to a specified location. Before transmitting this data value, the memory controller 63 may coalesce the data value with other data values retrieved from other memory chips 52.

Moreover, by implementing the aforedescribed techniques, various memory access errors can be prevented. In particular, when a transmission error causes the memory address received by a memory module 65 to be incorrect, the error detection logic 92 detects the transmission error and prevents an erroneous memory access based on the incorrect memory address.

Now, therefore, the following is claimed:

1. A system for preventing memory access errors, comprising:
a memory chip having a plurality of memory locations; and
logic external to the memory chip, the logic configured to receive a signal indicative of whether a received memory address is associated with a detected parity error, the logic further configured to enable the memory chip to access the memory locations based on the memory address if the signal indicates that the memory address is not associated with a detected parity error, and to disable the memory chip from accessing the memory locations based on the memory address if the signal indicates that the received address is associated with a detected parity error.

2. The system of claim 1, wherein the received memory address comprises chip select information, and wherein the logic is configured to disable the memory chip from accessing the memory locations based on the memory address by adjusting the chip select information.

3. The system of claim 1, wherein the memory address comprises an offset portion, the detected parity error associated with the offset portion.

4. The system of claim 1, wherein the memory address comprises an offset portion, the detected parity error associated with a portion of the memory address outside of the offset portion.

5. The system of claim 1, wherein the memory chip and the logic both reside on an integrated memory module.

6. The system of claim 5, further comprising a memory controller, wherein the integrated memory module is detachably coupled to the memory controller.

7. A system for preventing memory access errors, comprising:
a memory chip having a plurality of memory locations;
a memory controller configured to transmit a memory address for identifying one of the memory locations of the memory chip; and
logic external to the memory chip, the logic configured to receive a signal indicative of whether the memory address is associated with a detected parity error, the logic further configured to prevent the memory chip from accessing the memory locations based on the memory address if the signal indicates that the memory address is associated with a detected parity error.

8. The system of claim 7, wherein the memory controller is configured to receive a data access request and to transmit the memory address in response to the data access request, the memory controller further configured to map a bus address of the data access request to the one memory location.

9. The system of claim 7, wherein the memory address comprises chip select information, and wherein the logic is configured to prevent the memory chip from accessing the memory locations based on the memory address by adjusting the chip select information.

10. The system of claim 7, wherein the memory controller is configured to retransmit the memory address in response to the signal if the signal indicates that the memory address is associated with a detected parity error.

11. The system of claim 7, wherein the memory chip and the logic both reside on an integrated memory module.

12. The system of clam 11, wherein the memory module is detachably coupled to the memory controller.

13. A system for preventing memory access errors, comprising:
memory residing within a memory chip, the memory chip configured to receive a memory address, the memory address comprising chip select information; and
logic configured to receive a signal indicative of whether the memory address is associated with a parity error, the logic further configured to adjust the chip select information based on the received signal.

14. The system of claim 13, wherein the logic is external to the memory chip.

15. The system of claim 14, wherein the memory chip and the logic both reside on an integrated memory module.

16. A method for preventing memory access errors, comprising:
communicating a memory address for identifying one of a plurality of memory locations within a memory chip;
receiving, external to the memory chip, a signal indicative of whether the memory address is associated with a detected parity error;
analyzing, external to the memory chip, the signal received in the receiving step; and
disabling, based on the analyzing step, the memory chip from utilizing the memory address to access the memory locations.

17. The method of claim 16, wherein the memory address comprises chip select information, and wherein the disabling step comprises adjusting the chip select information.

18. A method for preventing memory access errors, comprising:
transmitting a memory address to a memory chip, the memory address comprising chip select information;
receiving a signal indicative of whether the memory address is associated with a parity error;
adjusting the chip select information based on the received signal; and
controlling, based on the chip select information, whether the memory chip performs a memory access in response to the memory address.

19. The method of claim 18, further comprising transmitting the chip select information, subsequent to the adjusting step, to the memory chip.

20. The method of claim 18, further comprising retransmitting the memory address to the memory chip in response to the signal if the signal indicates that the memory address is associated with a parity error.
